(19) United States
(12) Patent Application Publication
(10) Pub. No.: US 2024/0179878 A1
(43) Pub. Date: May 30, 2024

(54) REFRIGERATION SYSTEM AND DEVICE PROVIDED WITH REFRIGERATION APPARATUS

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shun WANG, Zhangjiakou City (CN)

(21) Appl. No.: 18/510,524

(22) Filed: Nov. 15, 2023

(30) Foreign Application Priority Data
Nov. 25, 2022 (CN) 202211493247.2

(51) Int. Cl. H05K 7/20

(52) U.S. Cl. CPC H05K 7/20827; H05K 7/20309; H05K 7/20318; H05K 7/20354

(57) ABSTRACT

The present disclosure discloses a refrigeration system and a device provided with a refrigeration apparatus. The refrigeration system includes an enclosed space and at least one first heat generating device installed in the enclosed space. An end of the first heat generating device is connected to a drainage apparatus and two heat exchange apparatuses. The drainage apparatus absorbs hot air generated by the first heat generating device to form a hot air flow, and causes the hot air flow to flow through the heat exchange apparatus, such that the heat exchange apparatus carries out heat exchange to form a cold air flow and discharges the cold air flow into the enclosed space.

### CROSS REFERENCE TO RELATED APPLICATION

This application claims priority to Chinese Patent Application No. 202211493247.2, titled “REFRIGERATION SYSTEM AND DEVICE PROVIDED WITH REFRIGERATION APPARATUS” and filed to the China National Intellectual Property Administration on Nov. 25, 2022, the entire contents of which are incorporated herein by reference.

### TECHNICAL FIELD

The present disclosure relates to the field of refrigeration devices, and more particularly, to a refrigeration system and a device provided with a refrigeration apparatus.

### BACKGROUND

In large data centers, whether in data rooms or power distribution rooms, refrigeration systems are required to dissipate heat, such that devices can operate at normal temperature to ensure safe operation of the devices.

Most of the existing refrigeration systems only use a set of refrigeration cycle. However, in practical applications, the refrigeration cycle often suffers from damage and shutdown, which may result in failure of timely and effective heat dissipation of the data centers, thereby adversely affecting reliability of the refrigeration systems.

### SUMMARY

An objective of the present disclosure is to provide a refrigeration system and a device provided with a refrigeration apparatus to improve reliability of the refrigeration system.

To achieve the above objective, an aspect of the present disclosure provides a refrigeration system, which includes an enclosed space and at least one first heat generating device installed in the enclosed space. An end of the first heat generating device is connected to a drainage apparatus and two heat exchange apparatuses. The drainage apparatus absorbs hot air generated by the first heat generating device to form a hot air flow, and causes the hot air flow to flow through the heat exchange apparatus, such that the heat exchange apparatus carries out heat exchange to form a cold air flow and discharges the cold air flow into the enclosed space.

To achieve the above objective, another aspect of the present disclosure also provides a device provided with a refrigeration apparatus, where the device is applied in an enclosed space. The device provided with the refrigeration apparatus at least includes a heat generating device, a heat exchange apparatus, and a drainage apparatus. The heat exchange apparatus and the drainage apparatus are connected to an end of the heat generating device, and the drainage apparatus is positioned between the heat exchange apparatus and the heat generating device. The drainage apparatus absorbs hot air generated by the heat generating device to form a hot air flow, and causes the hot air flow to flow through the heat exchange apparatus, such that the heat exchange apparatus carries out heat exchange to form a cold air flow and discharges the cold air flow into the enclosed space.

As can be seen from the technical solutions provided in the present disclosure, two heat exchange apparatuses are installed at an end of the first heat generating device. The two heat exchange apparatuses may be used alternately according to demands, to avoid failure of providing effective heat dissipation when a single heat exchange apparatus is damaged, thereby improving reliability of refrigeration of the refrigeration system. Of course, based on actual heat dissipation needs, either one of the two heat exchange apparatuses may be selected for use or the two heat exchange apparatuses may be used simultaneously to meet different heat dissipation needs.

Meanwhile, the first heat generating device, the heat exchange apparatuses and the drainage apparatus of the present disclosure are all installed in the enclosed space, and the heat exchange apparatuses and the drainage apparatus are arranged at an end of the first heat generating device. In this way, when the first heat generating device needs to be refrigerated, the drainage apparatus and the heat exchange apparatus may be started, such that the drainage apparatus generates an air flow flowing through the first heat generating device to generate hot air transmitted to the heat exchange apparatus, and the heat exchange apparatus carries out heat exchange to convert the hot air into cold air and discharges the cold air into the enclosed space. In this way, the hot air generated by the first heat generating device is limited between the heat exchange apparatus and the first heat generating device, such that other areas of the enclosed space are all in the cold air, to improve refrigeration air flow organization and enhance refrigeration energy efficiency, thereby reducing refrigeration energy consumption of a power distribution room.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a refrigeration system according to an embodiment of the present disclosure;

FIG. 2 is a schematic diagram showing a state of connection between a first heat generating device and two heat exchange apparatuses according to an embodiment of the present disclosure;

FIG. 3 is a schematic diagram showing a state of connection between the first heat generating device and the two heat exchange apparatuses according to another embodiment of the present disclosure; and

FIG. 4 is a schematic diagram showing a partial structure of the refrigeration system according to yet another embodiment of the present disclosure.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

In large data centers, whether in data rooms or power distribution rooms, refrigeration systems are required to dissipate heat, such that devices can operate at normal temperature to ensure safe operation of the devices.

Most of the existing refrigeration systems only use a set of refrigeration cycle. However, in practical applications, the refrigeration cycle often suffers from damage and shutdown, which may result in failure of timely and effective heat dissipation of the data centers, thereby adversely affecting reliability of the refrigeration systems.

In addition, taking the power distribution rooms as an example, the power distribution rooms mainly include transformers, low-voltage switchgear assemblies, and uninterruptible power supply (UPS) or high-voltage DC power supply (HVDC) devices. As the most major heat generating devices, the UPS or HVDC devices generate heat accounting for more than 70% of total heat generated in the power distribution rooms. In contrast, heat generated by the transformers only accounts for about 20% of the total heat. In terms of heat dissipation modes, air is supplied from bottom and discharged from top of front and rear surfaces of the transformers, and generally air is supplied from front and discharged from rear or supplied from front and discharged from top for the UPS and HVDC devices, which may lead to disordered airflow organization of the power distribution rooms, and may lead to a consequence that cold air supplied by the air conditioners cannot be sucked by heat generating devices unless the cold air is mixed with hot air. Therefore, to maintain a proper inlet air temperature of the transformers, of the UPS and HVDC devices, it is inevitable to require the air conditioners to supply the cold air with a lower temperature, which may lead to higher power consumption and higher energy consumption of the air conditioners.

Therefore, how to improve the structure of the refrigeration system to ensure the operational stability of the refrigeration system and reduce the refrigeration energy consumption has become an issue urgently to be solved in this field.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

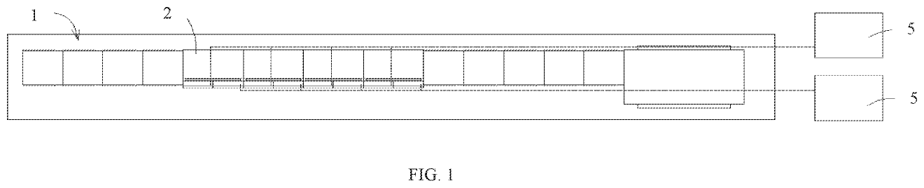

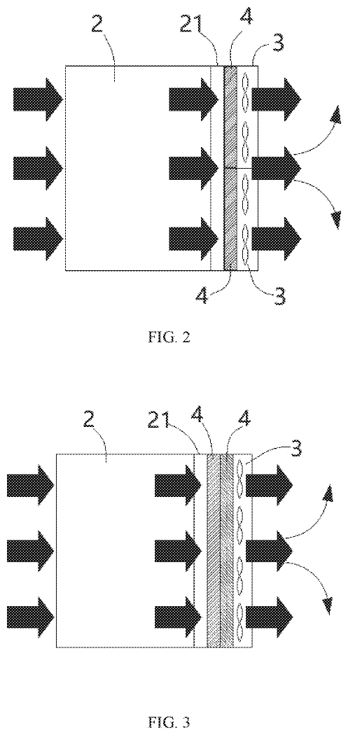

As shown in FIG. 1 and FIG. 2, in an implementable embodiment, the refrigeration system may at least include an enclosed space 1 and at least one first heat generating device 2, where the at least one first heat generating device 2 is installed in the enclosed space 1. An end of the first heat generating device 2 is connected to a drainage apparatus 3 and two heat exchange apparatuses 4. The drainage apparatus 3 absorbs hot air generated by the first heat generating device 2 to form a hot air flow, and causes the hot air flow to flow through the heat exchange apparatus 4, such that the heat exchange apparatus 4 carries out heat exchange to form a cold air flow and discharges the cold air flow into the enclosed space 1.

In this embodiment, the two heat exchange apparatuses 4 may be used alternately according to demands or operation states, to avoid failure of providing effective heat dissipation when a single heat exchange apparatus 4 is damaged, thereby improving reliability of refrigeration of the refrigeration system. Of course, based on actual heat dissipation needs, either one of the two heat exchange apparatuses 4 may be selected for use or the two heat exchange apparatuses 4 may be used simultaneously to meet different heat dissipation needs. For example, the enclosed space 1 may be provided with a temperature sensor. Based on a comparison between a temperature detected by the temperature sensor and a preset temperature, when the temperature detected by the temperature sensor is lower than the preset temperature, either one of the two heat exchange apparatuses 4 is selected for use. When the temperature detected by the temperature sensor is higher than the preset temperature, both the two heat exchange apparatuses 4 may be used simultaneously.

In practical applications, when the first heat generating device 2 needs to be refrigerated, the drainage apparatus 3 and the heat exchange apparatus 4 may be started, such that the drainage apparatus 3 generates an air flow flowing through the first heat generating device 2 to generate hot air transmitted to the heat exchange apparatus 4, and the heat exchange apparatus 4 carries out heat exchange to convert the hot air into cold air and discharges the cold air into the enclosed space 1. In this way, the hot air generated by the first heat generating device 2 is limited between the heat exchange apparatus 4 and the first heat generating device 2, such that other areas of the enclosed space 1 are all in the cold air, to improve refrigeration air flow organization and enhance refrigeration energy efficiency, thereby reducing refrigeration energy consumption of the power distribution room.

It should be pointed out that reference may be made to the existing technologies for the above drainage apparatus 3. For example, the drainage apparatus 3 is a fan component, which is comprised of a plurality of fans arranged in a rectangular array.

The above two heat exchange apparatuses 4 may be connected in parallel in one refrigeration cycle. Of course, to further improve the reliability of the refrigeration system, in an implementable embodiment, referring to FIG. 1 again, each of the heat exchange apparatuses 4 is connected to an outdoor unit 5, which should be positioned outside the enclosed space 1. That is, each heat exchange apparatus 4 forms a separate refrigeration cycle together with one outdoor unit 5, such that one second heat generating device 5 has two backup refrigeration cycles for use.

Further, the two heat exchange apparatuses 4 should be positioned between the drainage apparatus 3 and the first heat generating device 2. In this way, compared to a solution where the two heat exchange apparatuses 4 are arranged on a side of the drainage apparatus 3 far from the first heat generating device 2, an air flow rate passing through the heat exchange apparatuses 4 can be increased when the drainage apparatus 3 is started, which further improves heat dissipation effects.

As for modes of connection between the two heat exchange apparatuses 4 and the first heat generating device 2, the present disclosure provides two implementable embodiments.

In the first embodiment, as shown in FIG. 2, an end of the first heat generating device 2 is connected to two connection racks 21 arranged in a manner of double doors. There are provided two drainage apparatuses 3 respectively connected to the two connection racks 21. The two heat exchange apparatuses 4 are respectively connected to the two connection racks 21.

In the second embodiment, as shown in FIG. 3, an end of the first heat generating device 2 is connected to the connection rack 21. The two heat exchange apparatuses 4 are stacked and arranged on the connection rack 21, or the two heat exchange apparatuses 4 are arranged side by side on the connection rack 21.

It should be noted that the above two embodiments of the present disclosure are selected based on a width of an end of the first heat generating device, to avoid a case where the two heat exchange apparatuses 4 cannot be opened or closed due to a larger volume of the two heat exchange apparatuses 4 combined and a smaller volume of an end of the first heat generating device available for opening. In an selection mode, taking the heat generating device in the power distribution room as an example, when the width of an end of the first heat generating device exceeds 800 mm, the manner of double doors is adopted, that is, the arrangement mode in the first embodiment is adopted. When the width of an end of the first heat generating device is less than 800 mm, a manner of a single door is adopted, that is, the arrangement mode in the second embodiment is adopted.

In an implementable embodiment, the heat exchange apparatus 4 may be an evaporator. Correspondingly, the outdoor unit 5 at least includes a condenser, a compressor, and an expansion valve connected in series with each other. When there are provided a plurality of first heat generating devices 2, one of the two evaporators of a given one of the plurality of first heat generating devices 2 is connected in parallel with each other and then is communicated with one of the outdoor units 5 to form a refrigeration cycle; and the other one of the two evaporators of the given one of the plurality of first heat generating devices 2 is connected in parallel with each other and then is communicated with another one of the outdoor units 5 to form another refrigeration cycle. In this way, each first heat generating device 2 may have two backup refrigeration cycles for use, and arrangement of a plurality of outdoor units 5 may be avoided, thereby reducing manufacturing costs.

Each heat generating device in the enclosed space is refrigerated according to the refrigeration method of the first heat generating device. Of course, different refrigeration methods may be selected based on refrigeration capacities required for different heat generating devices.

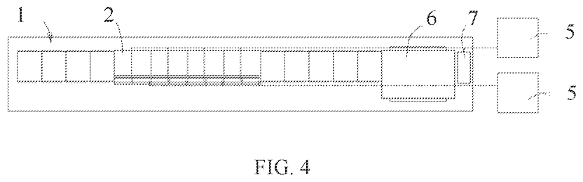

In an implementable embodiment, referring to FIG. 4 again, a second heat generating device 6 and an inter-row air conditioner 7 are further installed in the enclosed space 1. Heat generation capacity of the second heat generating device 6 is smaller than that of the first heat generating device 2. The inter-row air conditioner 7 is arranged on a side of the second heat generating device 6, and the inter-row air conditioner 7 is incorporated into one of the refrigeration cycles.

In this embodiment, the second heat generating device with a lower heat generation capacity may be refrigerated by the cold air in the enclosed space 1. However, to ensure the refrigeration effects, the inter-row air conditioner 7 may also be installed in the enclosed space 1, and the inter-row air conditioner 7 is arranged on a side of the second heat generating device 6 to assist the cold air in refrigeration to ensure the refrigeration effects.

Based on the same inventive concept, the present disclosure also provides a device provided with a refrigeration apparatus applied in the enclosed space 1, where device at least includes a heat generating device, a heat exchange apparatus 4, and a drainage apparatus 3. The heat exchange apparatus 4 and the drainage apparatus 3 are connected to an end of the heat generating device, and the drainage apparatus 3 is positioned between the heat exchange apparatus 4 and the heat generating device. The drainage apparatus 4 absorbs hot air generated by the heat generating device to form a hot air flow, and causes the hot air flow to flow through the heat exchange apparatus 4, such that the heat exchange apparatus 4 carries out heat exchange to form a cold air flow and discharges the cold air flow into the enclosed space 1.

Furthermore, number of the heat exchange apparatuses 4 is two, an end of the heat generating device is connected to a connection rack 21, and the two heat exchange apparatuses 4 are stacked and arranged on the connection rack 21. Alternatively, number of the heat exchange apparatuses 4 and number of the drainage apparatuses 3 both are two, and an end of the heat generating device is connected to two connection racks 21 arranged in a manner of double doors, the two heat exchange apparatuses 4 are respectively connected to the two connection racks 21, and the two drainage apparatuses 3 are respectively connected to the two connection racks 21.

It should be particularly pointed out that the above device provided with the refrigeration apparatus may be any device, such as a server in the data center, UPS, HVDC and transformers in the power distribution room, but the present disclosure is not limited thereto. Reference may be made to the above contents for specific structures and connectivity relationships between the heat exchange apparatus 4 and the drainage apparatus 3, which are not to be described in detail herein.

As can be seen from the technical solutions provided in the present disclosure, two heat exchange apparatuses are installed at an end of the first heat generating device. The two heat exchange apparatuses may be used alternately according to demands, to avoid failure of providing effective heat dissipation when a single heat exchange apparatus is damaged, thereby improving reliability of refrigeration of the refrigeration system. Of course, based on actual heat dissipation needs, either one of the two heat exchange apparatuses may be selected for use or the two heat exchange apparatuses may be used simultaneously to meet different heat dissipation needs.

Meanwhile, the first heat generating device, the heat exchange apparatuses and the drainage apparatus of the present disclosure are all installed in the enclosed space, and the heat exchange apparatuses and the drainage apparatus are arranged at an end of the first heat generating device. In this way, when the first heat generating device needs to be refrigerated, the drainage apparatus and the heat exchange apparatus may be started, such that the drainage apparatus generates an air flow flowing through the first heat generating device to generate hot air transmitted to the heat exchange apparatus, and the heat exchange apparatus carries out heat exchange to convert the hot air into cold air and discharges the cold air into the enclosed space. In this way, the hot air generated by the first heat generating device is limited between the heat exchange apparatus and the first heat generating device, such that other areas of the enclosed space are all in the cold air, to improve refrigeration air flow organization and enhance refrigeration energy efficiency, thereby reducing refrigeration energy consumption of a power distribution room.

Further, according to heat generation conditions of the devices in the power distribution room, the devices may be classified into the first heat generating device and the second heat generating device. In this way, according to actual refrigeration requirements, it may be selected whether the refrigeration apparatuses are installed for refrigeration or the refrigeration mode of combining the cold air with the inter-row air conditioner is used, thereby reasonably distributing the refrigeration apparatuses and reducing the refrigeration energy consumption.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A refrigeration system comprising an enclosed space and at least one first heat generating device, wherein the at least one first heat generating device is installed in the enclosed space;
an end of the first heat generating device is connected to a drainage apparatus and two heat exchange apparatuses; and
the drainage apparatus is configured to absorb hot air generated by the first heat generating device to form a hot air flow, and cause the hot air flow to flow through the heat exchange apparatus, such that the heat exchange apparatus carries out heat exchange to form a cold air flow and discharges the cold air flow into the enclosed space.

2. The refrigeration system according to claim 1, wherein each of the two heat exchange apparatuses is connected to an outdoor unit, and the outdoor unit is positioned outside the enclosed space.

3. The refrigeration system according to claim 2, wherein the two heat exchange apparatuses are positioned between the drainage apparatus and the first heat generating device.

4. The refrigeration system according to claim 3, wherein an end of the first heat generating device is connected to two connection racks arranged in a manner of double doors;
there are provided two drainage apparatuses respectively connected to the two connection racks; and
the two heat exchange apparatuses are respectively connected to the two connection racks.

5. The refrigeration system according to claim 3, wherein an end of the first heat generating device is connected to a connection rack; and
the two heat exchange apparatuses are stacked and arranged on the connection rack, or the two heat exchange apparatuses are arranged side by side on the connection rack.

6. The refrigeration system according to claim 4, wherein the heat exchange apparatus is an evaporator; and
correspondingly, the outdoor unit at least comprises a condenser, a compressor, and an expansion valve connected in series with each other.

7. The refrigeration system according to claim 6, wherein there are provided a plurality of the first heat generating devices;
one of the two evaporators of a given one of the plurality of first heat generating devices is connected in parallel with each other and then is communicated with one of the outdoor units to form a refrigeration cycle; and
the other one of the two evaporators of the given one of the plurality of first heat generating devices is connected in parallel with each other and then is communicated with another one of the outdoor units to form another refrigeration cycle.

8. The refrigeration system according to claim 7, wherein a second heat generating device and an inter-row air conditioner are further installed in the enclosed space;
heat generation capacity of the second heat generating device is smaller than heat generation capacity of the first heat generating device; and
the inter-row air conditioner is arranged on a side of the second heat generating device, and the inter-row air conditioner is incorporated into one of the refrigeration cycles.

9. A device provided with a refrigeration apparatus being applied in an enclosed space, wherein the device provided with the refrigeration apparatus at least comprises a heat generating device, a heat exchange apparatus, and a drainage apparatus;
the heat exchange apparatus and the drainage apparatus are connected to an end of the heat generating device, and the drainage apparatus is positioned between the heat exchange apparatus and the heat generating device; and
the drainage apparatus is configured to absorb hot air generated by the heat generating device to form a hot air flow, and cause the hot air flow to flow through the heat exchange apparatus, such that the heat exchange apparatus carries out heat exchange to form a cold air flow and discharges the cold air flow into the enclosed space.

10. The device provided with the refrigeration apparatus according to claim 9, wherein number of the heat exchange apparatuses is two, an end of the heat generating device is connected to a connection rack, and the two heat exchange apparatuses are stacked and arranged on the connection rack;
or
number of the heat exchange apparatuses and number of the drainage apparatuses both are two, and an end of the heat generating device is connected to two connection racks arranged in a manner of double doors, the two heat exchange apparatuses are respectively connected to the two connection racks, and the two drainage apparatuses are respectively connected to the two connection racks.

11. The device provided with the refrigeration apparatus according to claim 10, wherein each of the two heat exchange apparatuses is connected to an outdoor unit, and the outdoor unit is positioned outside the enclosed space.

12. The device provided with the refrigeration apparatus according to claim 11, wherein the heat exchange apparatus is an evaporator; and
correspondingly, the outdoor unit at least comprises a condenser, a compressor, and an expansion valve connected in series with each other.
